(19) United States
(12) Patent Application Publication
(10) Pub. No.: US 2021/0238027 A1
(43) Pub. Date: Aug. 5, 2021

(54) SYSTEMS, DEVICES, AND METHODS TO REDUCE DIELECTRIC CHARGING IN MICRO-ELECTRO-MECHANICAL SYSTEMS DEVICES

(71) Applicant: wiSpry, Inc., Irvine, CA (US)

(72) Inventors: Dana Richard DeReus, Santa Ana, CA (US); Arthur S. Morris, III, Lakewood, CO (US); David Molinero-Giles, Irvine, CA (US)

(21) Appl. No.: 17/234,108

(22) Filed: Apr. 19, 2021

Related U.S. Application Data
(63) Continuation-in-part of application No. 14/875,341, filed on Oct. 5, 2015.
(60) Provisional application No. 62/059,822, filed on Oct. 3, 2014.

(51) Int. Cl. B81B 3/00

(52) U.S. Cl. CPC B81B 3/0008; B81B 3/001

(57) ABSTRACT

The present subject matter relates to devices, systems, and methods for isolation of electrostatic actuators in MEMS devices to reduce or minimize dielectric charging. A tunable component can include a fixed actuator electrode positioned on a substrate, a movable actuator electrode carried on a movable component that is suspended over the substrate, one or more isolation bumps positioned between the fixed actuator electrode and the movable actuator electrode, and a fixed isolation landing that is isolated within a portion of the fixed actuator electrode that is at, near, and/or substantially aligned with each of the one or more isolation bumps. In this arrangement, the movable actuator electrode can be selectively movable toward the fixed actuator electrode, but the one or more isolation bumps can prevent contact between the fixed and movable actuator electrodes, and the fixed isolation landing can inhibit the development of an electric field in the isolation bump.

### CROSS-REFERENCE TO RELATED APPLICATIONS

The present application is a continuation patent application of and claims priority to U.S. application Ser. No. 14/875,341, filed Oct. 5, 2015, which claims the benefit of U.S. Provisional Patent Application Ser. No. 62/059,822, filed Oct. 3, 2014, the disclosures of which are incorporated herein by reference in their entireties.

### TECHNICAL FIELD

The subject matter disclosed herein relates generally to tunable micro-electro-mechanical systems (MEMS) components. More particularly, the subject matter disclosed herein relates to isolation of electrostatic actuators in MEMS devices to reduce or minimize dielectric charging.

### BACKGROUND

In the construction of micro-electro-mechanical systems (MEMS) devices in which electrostatic actuator plates are movable with respect to one another between open and closed states, the actuator plates would become shorted if the MEMS device closed and the actuators came into contact. To prevent actuator contact and shorting, one or both of the actuator electrodes can be covered by a dielectric that has the appropriate thickness to prevent dielectric breakdown. The continuous dielectric provides the appropriate isolation so that shorting and breakdown can be prevented, but significant contact area may be created within high field regions that can charge and thus lead to reduced lifetimes caused by dielectric charging. The contact area can be minimized by breaking the continuous dielectric pattern into discontinuous or isolated dielectric features, isolation features, or isolation bumps, but even these solutions do not fully address the charging issues.

### SUMMARY

In accordance with this disclosure, devices, systems, and methods for isolation of electrostatic actuators in MEMS devices are provided to reduce or minimize dielectric charging. In one aspect, a tunable component is provided. The tunable component can include a fixed actuator electrode positioned on a substrate, a movable actuator electrode carried on a movable component that is suspended over the substrate, one or more isolation bumps positioned between the fixed actuator electrode and the movable actuator electrode, and a fixed isolation landing that is isolated within a portion of the fixed actuator electrode that is at, near, and/or substantially aligned with each of the one or more isolation bumps. In this arrangement, the movable actuator electrode can be selectively movable toward the fixed actuator electrode, but the one or more isolation bumps can prevent contact between the fixed actuator electrode and the movable actuator electrode, and the fixed isolation landing can inhibit the development of an electric field in the isolation bump.

In another aspect, a method for manufacturing a tunable component can include depositing a fixed actuator electrode on a substrate, defining one or more fixed isolation landing that is isolated within a portion of the fixed actuator electrode, depositing a sacrificial layer over the fixed actuator electrode, forming a recess into the sacrificial layer that is at, near, and/or substantially aligned with the one or more fixed isolation landing, depositing an isolation bump in each of the one or more recess, depositing a movable actuator electrode over the sacrificial layer, and removing the sacrificial layer to release the movable actuator electrode, wherein the movable actuator electrode is selectively movable toward the fixed actuator electrode.

Although some of the aspects of the subject matter disclosed herein have been stated hereinabove, and which are achieved in whole or in part by the presently disclosed subject matter, other aspects will become evident as the description proceeds when taken in connection with the accompanying drawings as best described hereinbelow.

### BRIEF DESCRIPTION OF THE DRAWINGS

The features and advantages of the present subject matter will be more readily understood from the following detailed description which should be read in conjunction with the accompanying drawings that are given merely by way of explanatory and non-limiting example, and in which:

FIG. 1 is a side view of a MEMS tunable capacitor die according to an embodiment of the presently disclosed subject matter;

FIGS. 2A through 2D and FIGS. 3A through 5 are side cutaway views of a configuration for isolation of electrostatic actuators in MEMS devices according to embodiments of the presently disclosed subject matter;

FIG. 2E is a top view of a configuration for isolation of electrostatic actuators in MEMS devices according to some embodiments of the presently disclosed subject matter;

FIGS. 6 and 7 are graphs illustrating voltage contours in a region around an isolation bump between electrostatic actuators according to embodiments of the presently disclosed subject matter;

FIGS. 8 and 9 are graphs illustrating electric fields at a center of an isolation bump between electrostatic actuators according to embodiments of the presently disclosed subject matter; and

FIGS. 10A through 13B are side cutaway views of a configuration for isolation of electrostatic actuators in MEMS devices according to embodiments of the presently disclosed subject matter.

### DETAILED DESCRIPTION

The present subject matter provides improved isolation of electrostatic actuators in MEMS devices to reduce or minimize dielectric charging. In one aspect, the present subject matter provides configurations for actuator electrodes that provide isolation of electric fields in a region at, near, and/or substantially aligned with an isolation bump that maintains a desired minimum spacing between two actuator electrodes.

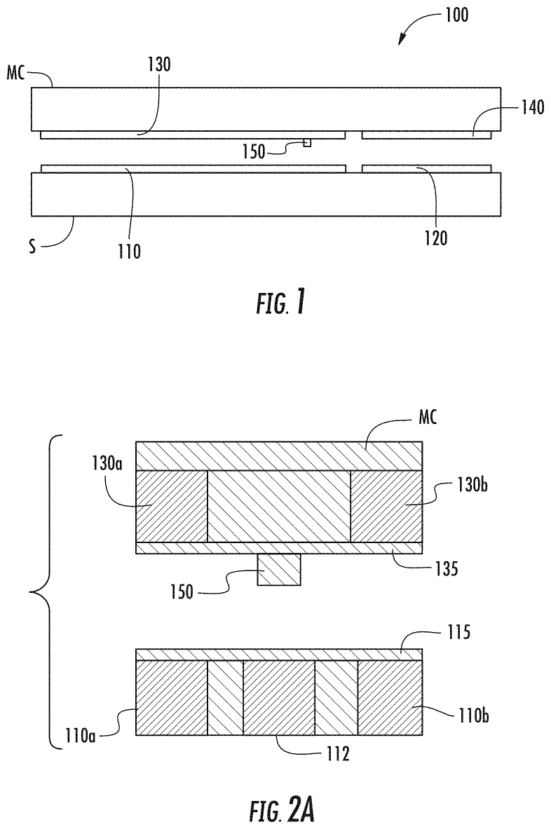

In particular, for example, in some configurations for a MEMS tunable device, an array of individual tunable components is provided. As shown in FIG. 1, for example, each tunable component, generally designated 100, comprises one or more fixed actuator electrode 110 provided on a substrate S. A corresponding one or more movable actuator electrode 130 can be carried on a movable component MC that is spaced apart from substrate S by a gap. Furthermore, in some embodiments, tunable component 100 can be a tunable capacitor that further comprises one or more fixed capacitor electrode 120 provided on substrate S and one or more movable capacitor electrode 140 carried on movable component MC. Movable actuator electrode 130 and movable capacitor electrode 140 can be substantially aligned with fixed actuator electrode 110 and fixed capacitor electrode 120, respectively.

In some embodiments, such a structure can be formed by a layer-by-layer deposition process in which fixed actuator electrode 110 is deposited on substrate S, a sacrificial layer is deposited over fixed actuator electrode 110, movable actuator electrode 130 and the other elements of movable component MC are deposited over the sacrificial layer, and the sacrificial layer is removed (e.g., by etching) to release movable component MC. In this arrangement, movable component MC can be moved with respect to the fixed elements and substrate S by controlling the potentials applied to fixed actuator electrode 110 and to movable actuator electrode 130. In some embodiments, for example, movable actuator electrode 130 can be connected to a ground potential and fixed actuator electrode 110 can be connected to a high voltage to cause an electrostatic attraction between the actuator electrodes to cause movable component MC to deflect towards substrate S.

In some embodiments, the fixed and moving electrodes (i.e., one or more of fixed actuator electrode 110, fixed capacitor electrode 120, movable actuator electrode 130, and/or movable capacitor electrode 140) are encapsulated by one or more dielectric material layers to remove or at least reduce the possibility of direct electrical shorting between electrodes during operation (e.g., when movable component MC is deflected to a “closed” position in which the gap between the electrodes is minimized). Even in such arrangements, however, the large area of contact between the actuator elements can lead to excessive dielectric charging and result in large forces, which can affect operation and reliability.

Accordingly, in some embodiments, one or more isolation bump 150 can be provided between respective fixed and movable electrodes (e.g., between fixed actuator electrode 110 and movable actuator electrode 130) to help minimize the contact area and reduce the electric field over much of the actuator area. Referring again to the exemplary layer-by-layer deposition process discussed above, one or more isolation bump 150 can be formed by forming a recess into the sacrificial layer deposited over substrate S and depositing an isolation bump in each of the one or more recess. Such isolation bumps can be implemented in any of a variety of particular shapes (e.g., rectangular prism, octagonal prism) or configurations to optimize mechanical operation and reliability of the device.

In some embodiments, for example, tall isolation bumps (e.g., having a height of about 0.5 μm) located further from a center of the capacitor elements can provide comparatively greater isolation over the entire length of the actuator area, provide mechanical stability, and limit actuator excursion and thus induced material stress. Alternatively or in addition, short isolation bumps (e.g., having a height of about 0.2 μm) can be provided elsewhere in the actuator area to prevent local actuator contact or collapse, particularly near the capacitor region. In some particular configurations, shorter isolation bumps can be distributed either uniformly across the actuator area or in optimal, discrete locations. The optimal number and placement of these isolation bumps for a MEMS capacitor can be determined from the minimum required to achieve stable capacitance; to achieve a flat CV response above pull-in, including minimizing the likelihood of primary/secondary actuator collapse between the actuator and the capacitor or primary actuator collapse between the major isolation bumps and the beam tip; and/or to minimize the increase in the pull-in voltage. Increasing the height of the isolation bumps also works to minimize any field generated charge, but the bump height is limited by the need to maintain sufficient forces in the down state to provide stable capacitance. These and other exemplary configurations for such isolation bumps are discussed in more detail in U.S. Pat. No. 6,876,482 and co-pending U.S. patent application Ser. No. 14/033,434, the disclosures of which are incorporated herein in their entireties.

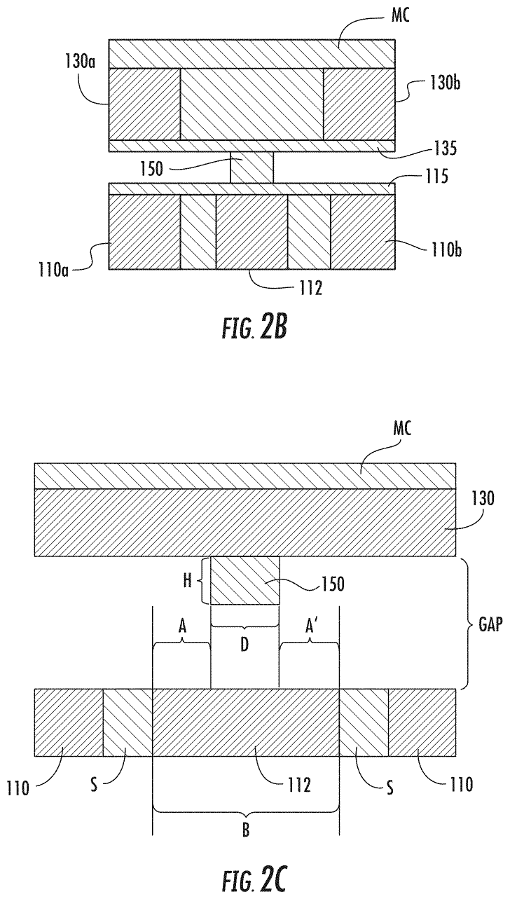

Regardless of the particular arrangement, one or more isolation bump 150 can be designed to occupy a minimal area with respect to the nearby electrodes, to be minimal in number, and/or to have such a height to minimize electric fields with in the context of other functional requirements. To further improve the effects of the electric fields in the region around isolation bump 150, portions of the field-inducing electrodes can be removed from the region around isolation bump 150. In one particular configuration illustrated in FIGS. 2A and 2B, for example, isolation bump 150 is attached to movable component MC between fixed actuator electrode 110 and movable actuator electrode 130. In addition, in some embodiments, to further prevent actuator contact and shorting, a fixed dielectric layer 115 (e.g., SiO₂, Al₂O₃) can be provided on fixed actuator electrode 110 (i.e., on a surface of fixed actuator electrode 110 that faces movable actuator electrode 130) and/or a movable dielectric layer 135 (e.g., SiO₂) can be provided on movable actuator electrode 130 (i.e., on a surface of movable actuator electrode 130 that faces fixed actuator electrode 110). Fixed dielectric layer 115 and movable dielectric layer 135 can be composed of the same material or different dielectric materials.

In the portion of movable actuator electrode 130 at or around the point at which isolation bump 150 is attached (e.g., above isolation bump 150 in the orientation shown in FIGS. 2A and 2B), movable actuator electrode 130 can be patterned with a hole above the bump such that a first movable electrode portion 130a and a second movable electrode portion 130b surround isolation bump 150 but do not overlap with it. Furthermore, in the illustrated configuration, the portion of fixed actuator electrode 110 at or near a position where isolation bump 150 would contact fixed actuator electrode 110 (e.g., directly below isolation bump 150 in the orientation shown in FIGS. 2A and 2B) is patterned with a fixed isolation landing 112 positioned between a first fixed actuator portion 110a and a second fixed actuator portion 110b of fixed actuator electrode 110 (e.g., with intervening sections of dielectric material therebetween).

In a particular exemplary configuration, for instance, isolation bump 150 can have an effective diameter of approximately 0.4 μm and a height of approximately 250 nm, and fixed isolation landing 112 can have substantially rectangular dimensions within fixed actuator electrode 110 with dimensions of about 2.1 μm×1.5 μm. In some embodiments, the spacing between fixed actuator electrode 110 and fixed isolation landing 112 is approximately 1 μm. Isolation bump 150 can be substantially centered within fixed isolation landing 112, or it can be offset with respect to a center of fixed isolation landing 112.

In another particular exemplary configuration, a larger embodiment of isolation bump 150 can have an effective diameter of approximately 0.6 μm and a height of approximately 550 nm compared to fixed isolation landing 112 having dimensions of about 7.7 μm×7 μm.

FIG. 2C and FIG. 2D illustrate an example moveable component and fixed actuator electrode similar to that illustrated in FIG. 2A and FIG. 2B. As described above, there are various sizes and dimensions of the various components. In some embodiments, these sizes and dimensions can be chosen to minimize dielectric charging or electrification in contact areas (i.e., where the isolation bump 150 contacts the isolation landing 112 or where the isolation bump 150 contacts the movable electrode) by reducing the electric field at and around these points of contact. Dielectric charging is formed when two surface areas are in contact, where electron and/or ions travel from one surface to other creating a misbalanced of charge. This charge transfer or surface electrification is strongly enhanced by an electric field. Charge misbalance can deteriorate the MEMS performance and ultimately create failure by stiction, where the electric field created by the charge misbalance is high enough that the electrostatic force overcomes the MEMS mechanical restoring force. Thus, it is beneficial to minimize the electric charge in and near locations where two surface areas are in contact.

Described herein are various ranges for the dimensions of some of the components in FIG. 2C and FIG. 2D. In some embodiments, a ratio of a first distance A, the first distance A being the smallest lateral distance between an edge of the isolation bump 150 and an edge of the fixed isolation landing 112, to a second distance S, the second distance S being a distance between an edge of the isolation landing 112 and an edge of the fixed actuator electrode 110, is greater than 0.5 to 1 and less than 4 to 1. In some embodiments, the isolation bump 150 will land in the middle of the isolation landing 112, in which case, the first distance A will be the present on both sides of the isolation bump 150. However, in some embodiments, for various reasons (i.e., taking into account both intentional and tolerance mis-alignments), the isolation bump 150 will not land directly in the center of the isolation landing 112. In this case, the first distance A will be on the side where the edge of the isolation bump 150 is closest to the edge of the isolation landing 112 and on the exact opposite side of the isolation bump 150, the distance between the edge of the isolation bump 150 and the edge of the isolation landing 112 (i.e. on the opposite side from the first distance A) will be referred to as distance A′ (i.e., as shown in FIG. 2C). In some embodiments, distance A′ is almost identical to the first distance A, depending on the variances and intentional and tolerance mis-alignments.

Alternatively, in some embodiments, the first distance A is between, and including, about 1 and 10 times the height H (described hereinbelow) of a respective isolation bump 150. For example and without limitation, the first distance A is about 2 times greater than the height H of the respective isolation bump 150. In some embodiments, all of the isolation bumps 150 can have the same or different dimensions. In any event, the dimension of the first distance A as well as the other dimensions discussed herein are chosen to minimize the electric charge build-up where the isolation bump 150 contacts the isolation landing 112. As described herein, the distance A′ will be the length B of the isolation landing 112 minus the diameter D of the isolation bump 150 and the length of the first distance A. The possible values of the length B of the isolation landing 112 minus the diameter D of the isolation bump 150 are described herein.

The GAP is defined as the distance between the movable electrode 130 (including any surface materials shown in other figures herein) and the fixed electrode 110. In some embodiments, the dimension of the GAP is equal to or greater than the height H of the isolation bump 150 as defined below. The dimension of the GAP is further limited by the maximum MEMS opening distance. In other words, the maximum dimension of the GAP is the distance between the movable electrode 130 (including any surface materials shown in other figures herein) and the fixed electrode 110 when the MEMS device is in a fully “OPEN” position. In some embodiments, the dimension of the GAP can range between, and including, about 0.5 microns and 5 microns. More particularly, in some embodiments, the dimension of the GAP can range between, and including, about 1 and 2 microns.

As described herein, in some embodiments, the isolation bump 150 can have a height H and a diameter D, the height H being defined as the length in which the isolation bump 150 extends into the GAP, and the diameter D being defined as the dimension of the isolation bump 150 measured in a direction perpendicular to the measurement of the height H of the isolation bump 150. In some embodiments, the height H of the isolation bump 150 can range between, and including, about 1% and 30% of the GAP dimension when the MEMS device is in a fully “OPEN” position. For example and without limitation, in some embodiments, the height H can be between, and including, about 0.005 and 1.5 microns. In some alternative embodiments in particular, the height H of the isolation bump 150 can be about 20% of the GAP, or about 0.2 to 0.4 microns. In some further embodiments, the diameter D can range between, and including, about 1 to 10 times the height H. In some embodiments, the diameter D can be between, and including, about 0.005 and 15 microns. More particularly, in some embodiments, the diameter D can be between, and including, about 0.2 to 4 microns.

Those having ordinary skill in the art can appreciate that the length B of the isolation landing 112 can range based on the dimensions of the first distance A, the diameter D of the bump 150, and where the isolation bump 150 lands on the isolation landing 112. For example and without limitation, if the isolation bump 150 lands in the middle of the isolation landing 112, the length B of the isolation landing 112 is equal to 2*A+D as defined above. In the instance where the isolation bump 150 does not land directly in the center of the isolation landing 112, the length B of the isolation landing 112 is equal to A+A′+D, where the first distance A is, again, the shortest distance from the edge of the isolation bump 150 and the edge of the isolation landing 112 and the distance A′ is the distance on the opposite side of the isolation bump 150 as the first distance A. In some embodiments, the length B of the fixed isolation landing 112 can be between, and including, 0.015 micron and 45 microns. To obtain this range, assume two hypotheticals: a low range hypothetical and a high range hypothetical.

Both hypotheticals assume that the isolation bump 150 lands directly in the center of the isolation landing 112, in which case the length B of the isolation landing 112 is B=2*A+D. As described above, both the diameter of the isolation bump 150 and the first distance A can be between and including 1-10 times the height H of the bump 150. The height H of the bump 150 can be between, and including, about 0.005 and 1.5 microns. Therefore, on the low-end hypothetical, B=2*(0.005)+0.005 microns which is equal to 0.015 microns. On the high-end hypothetical, the same assumptions are made, except that B=2*(15)+15 microns, which is equal to 45 microns. In particular, in some embodiments, the fixed isolation landing 112 can have a length B that is between, and including, about 2 μm and 21 μm.

In embodiments where the isolation bump 150 lands away from the center of the isolation landing 112, the length B would still range in the measurements described above, however, the first length A would be smaller and the length A′ on the opposite side of the isolation bump 150 would be greater than the first length A. In such embodiments, the length A′ would be greater than or equal to the ranges of lengths described above for the first length A.

In some embodiments, the second distance S is the spacing between fixed actuator electrode 110 and the fixed isolation landing 112. In some embodiments, the second distance S can range between, and including, about 1 and 10 times the height H of the isolation bump 150. Similarly to the first length A and A′ described above, both spacings on either side of the isolation landing 112 may have slightly different lengths, depending on the manufacturing process for the MEMs device. Therefore the second length S could be the same on both sides of the isolation landing 112, or there could be a second length S and S′ scenario where the second length S is nominally different than the length S′ on the other side of the isolation landing 112.

FIG. 2E illustrates a top view of an example isolation bump 150 landing upon the isolation landing. Although in this illustration the isolation bump 150 and the isolation landing 112 are both circular in shape, those having ordinary skill in the art will appreciate that the isolation bump 150 and the isolation landing 112 can have a cross section of any suitable shape including, for example and without limitation, circular, hexagonal, octagonal, square, etc. In addition, the isolation landing 112 can be surrounded by the spacing S as described herein, which separates the isolation landing 112 from the fixed actuator electrode 110. Furthermore, the isolation landing 112 can be connected to a wire W which is also isolated from the fixed actuator electrode 110.

Moreover, in some embodiments, all of the isolation bumps 150 have the same dimensions and are identical in shape and size. In other embodiments, each of the isolation bumps 150 are different in size and shape from one another according to design requirements. In some other embodiments, different groups of the isolation bumps 150 can have the same dimensions. For example, as a hypothetical, if there were 10 isolation bumps, there could be four separate groups, 1, 2, 3, and 4. All of the bumps in group 1 could have the same size and shape all of the bumps in group 2 could have the same size and shape, and so on. However, this is a hypothetical. There could be any number of different groups or there could be just one or two.

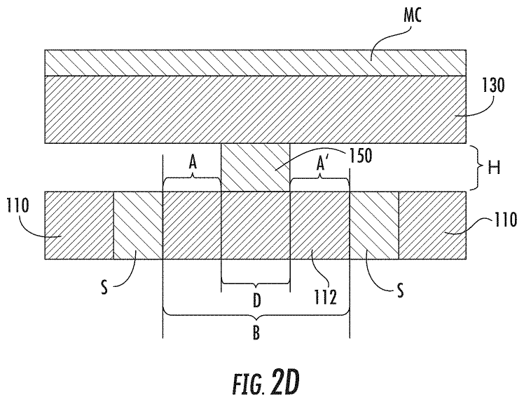

In an alternative configuration shown in FIGS. 3A and 3B, rather than a hole being provided in movable actuator electrode 130 at or near the position at which isolation bump 150 is attached, movable actuator electrode 130 in a region of isolation bump 150 can be substantially unpatterned (i.e., continuously spanning across substantially the entire width of isolation bump 150). In this configuration, fixed actuator electrode 110 can again be patterned to have a fixed isolation landing 112 in the region of fixed actuator electrode 110 at which isolation bump 150 would contact in a closed state.

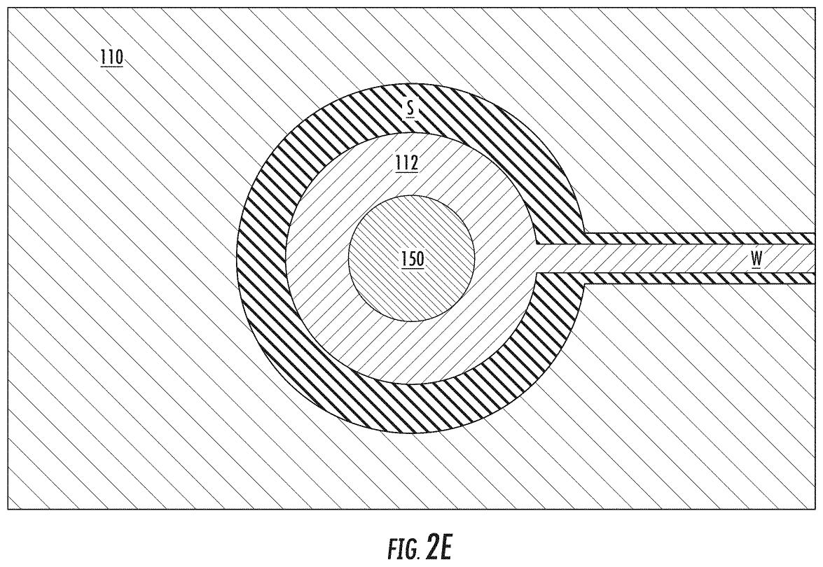

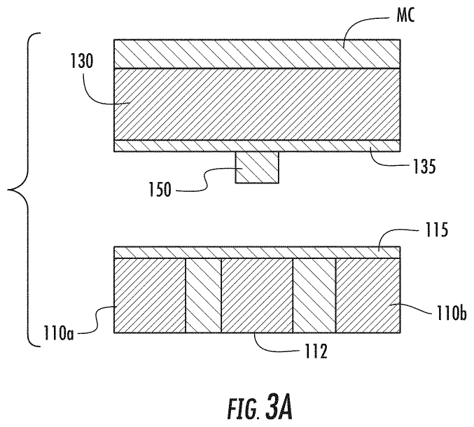

In yet further exemplary configurations illustrated in FIGS. 4 and 5, isolation bump 150 can be attached or otherwise provided on the fixed portion of tunable component 100, with either a patterned hole in movable actuator electrode 130 (See, e.g., FIG. 4) or movable actuator electrode 130 being substantially unpatterned (See, e.g., FIG. 5). In some embodiments having such a configuration, isolation bump 150 can be fabricated on fixed dielectric layer 115 and extend into the gap between fixed actuator electrode 110 and movable actuator electrode 130. In these embodiments, the manufacturability of tunable component 100 can be improved since it can be easier to align isolation bump 150 with fixed isolation landing 112 when it is formed directly on fixed isolation landing 112 rather than being suspended above fixed isolation landing 112. In this regard, in embodiments in which isolation bump 150 is attached to movable component MC, there can be more process steps required between the formation of fixed isolation landing 112 and isolation bump 150, and thus there is a higher likelihood that a misalignment may occur in one of the intervening steps. Furthermore, in some embodiments and implementations, movable component MC can expand or contract slightly on release, which can also induce misalignment if such alteration to the beam shape is not taken into account in the design, such as through a designed offset of the alignment of isolation bump 150 with respect to fixed isolation landing 112, expanding the size of fixed isolation landing 112 to allow for a greater tolerance of relative movement, or both. That being said, providing isolation bump 150 on fixed isolation landing 112 can make other aspects of manufacture more difficult since the additional topography can make it more complicated to planarize a sacrificial layer deposited over the fixed components (e.g., to form the gap between fixed actuator electrode 110 and movable actuator electrode 130).

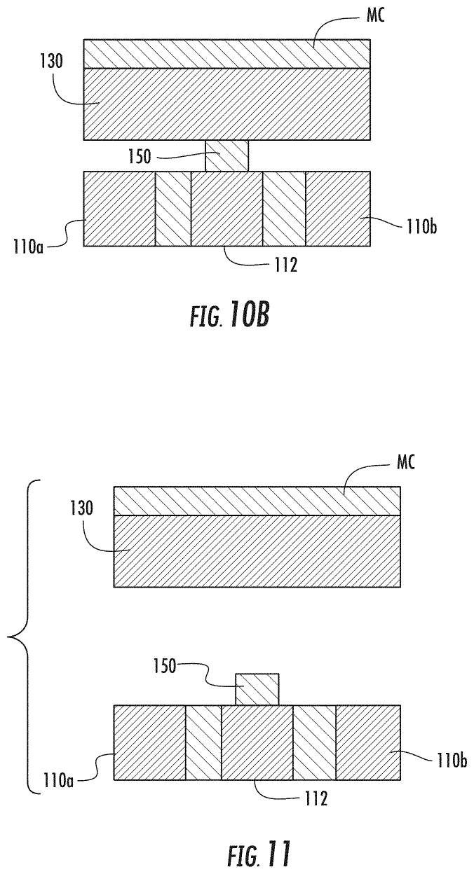

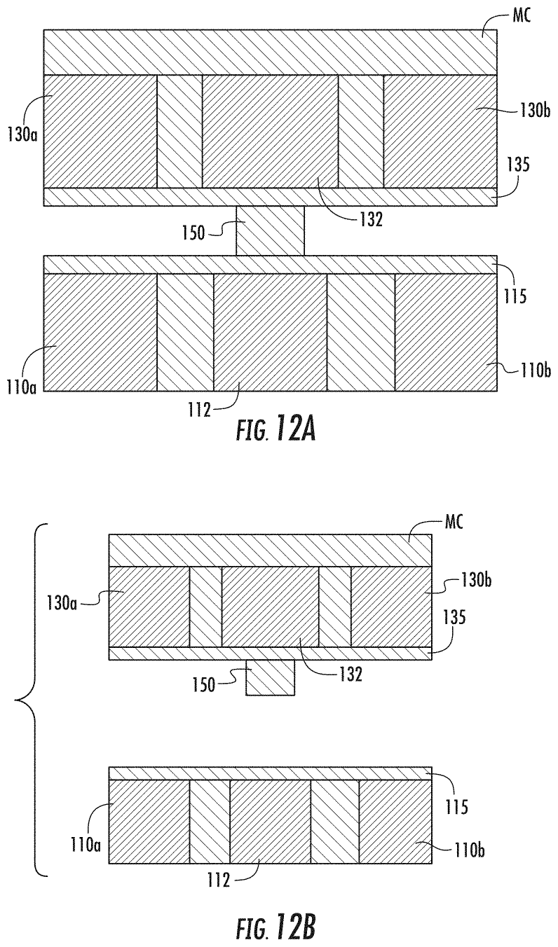

Still further exemplary configurations are shown in FIGS. 10A and 10B, wherein isolation bump 150 is attached to movable actuator electrode 130, and the region of contact with the fixed elements is a fixed isolation landing 112 positioned between first and second actuator portions 110a and 110b, but fixed dielectric layer 115 and movable dielectric layer 135 are omitted. Likewise, FIG. 11 illustrates a similar exemplary configuration in which isolation bump 150 is attached at fixed isolation landing 112. In this configuration, isolation bump 150 can be fabricated directly on fixed isolation landing 112 or is directly attached to movable actuator electrode 130.

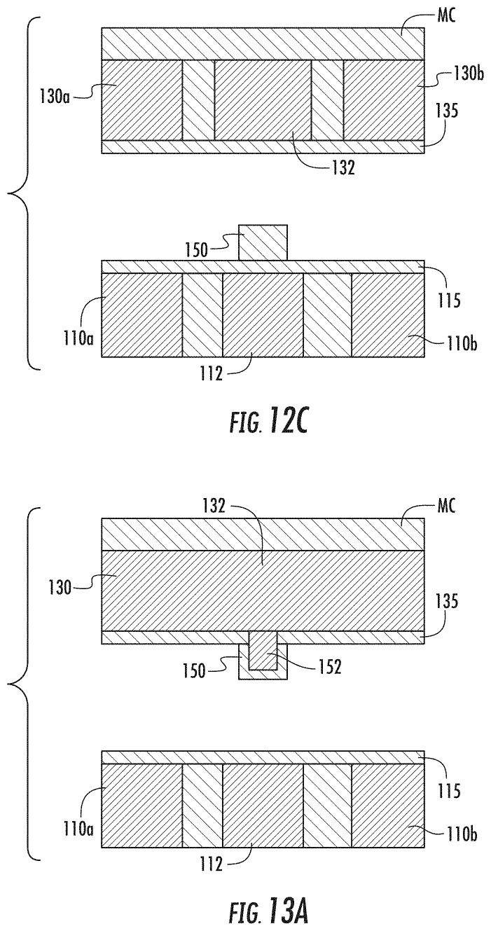

In yet a further alternative configuration, FIGS. 12A-12C illustrate arrangements in which movable actuator electrode 130 is modified to include a movable isolation fill 132 (e.g., tungsten) at, near, or substantially aligned with isolation bump 150. This variation adds complexity to the manufacture process, and it can exhibit some drawbacks if movable isolation fill 132 is left floating, as it may eventually charge. That being said, in some embodiments, high voltage can be applied to the movable actuator electrode 130 (i.e., to first and second movable actuator portions 130a and 130b) instead of to fixed actuator electrode 110 (i.e., to first and second fixed actuator portions 110a and 110b), and movable isolation fill 132 can be grounded to achieve the desired function.

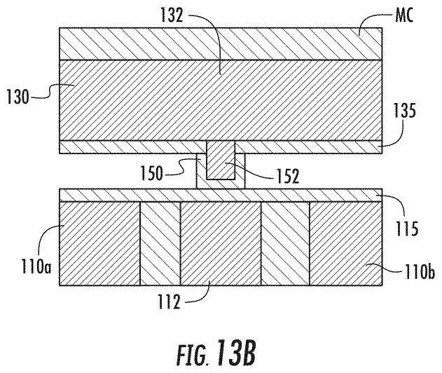

In another alternative configuration, FIGS. 13A and 13B illustrate arrangements in which isolation bump 150 is itself provided with an isolation bump metal fill 152. As shown in this configuration, isolation bump metal fill 152 can be in communication with movable actuator electrode 130 and can be held at a common potential. Such a configuration can improve the manufacturability of the device without significantly detrimentally affecting the operation compared to configurations in which isolation bump 150 does not include isolation bump metal fill 152. In particular, it may be much easier to form isolation bump 150 in this manner since movable dielectric layer 135 and isolation bump 150 can be formed in a single deposition, and movable actuation electrode 130 and isolation bump metal fill 152 can thereafter likewise be formed in a single deposition. In contrast, in configurations in which isolation bump 150 is composed substantially entirely of a dielectric material, the formation of such a structure can require that enough insulator material be deposited to fill the hole in the sacrificial material. This process step can result in movable dielectric layer 135 becoming thicker than desired unless it were planarized, which is feasible but would increase the cost and/or effort of the process.

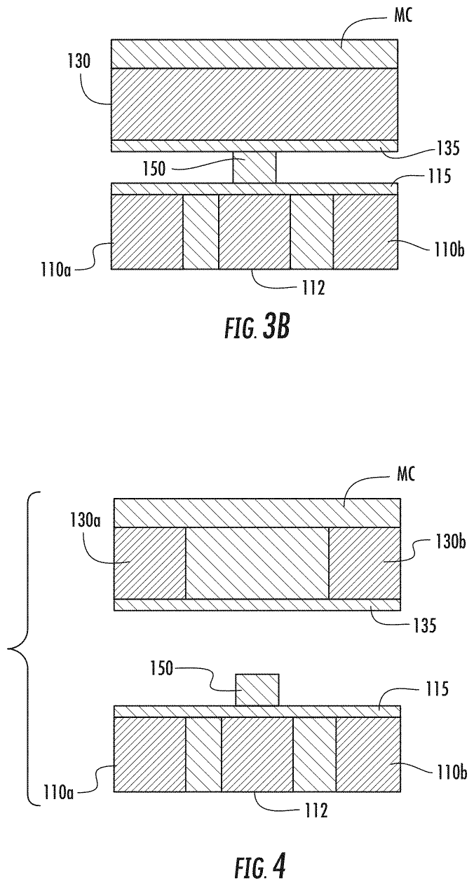

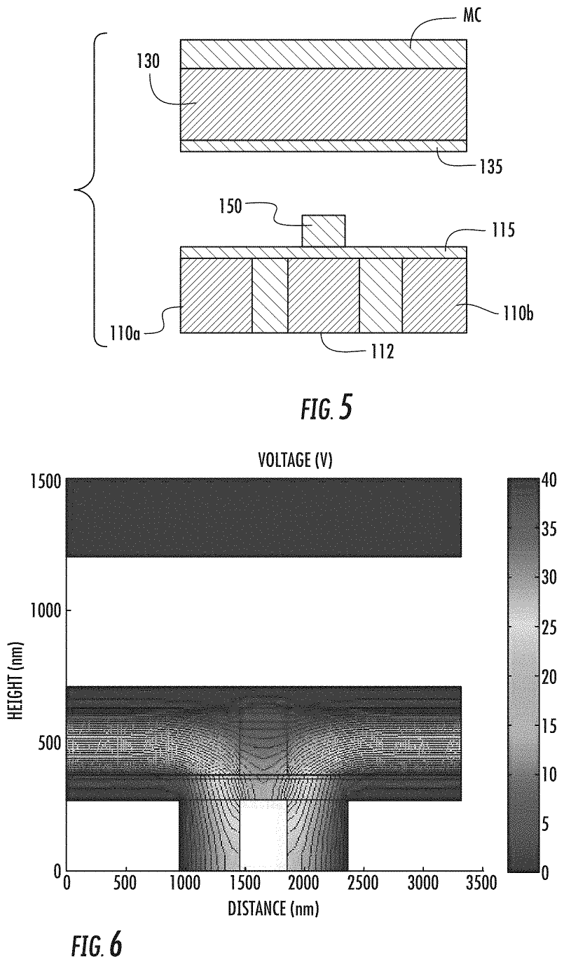

In any of these arrangements, those having skill in the art will appreciate that the configuration of the electrode portions that are at, near, or substantially in alignment with isolation bump 150 can affect the ability for a charge to develop through isolation bump 150 between the electrodes. In particular, for example, fixed isolation landing 112 can be electrically isolated (“floating”), connected to a ground potential, or connected to a selected electrical potential that is the same as or different than the potential connected to the movable actuator electrode 130. As shown in FIG. 6, for example, a graph of voltage contours are shown for a configuration for tunable component 100 in which fixed isolation landing 112 is electrically isolated/floating and where movable actuator electrode 130 is continuous (See, e.g., FIGS. 3A, 3B, and 5) above fixed actuator electrode 110 and fixed isolation landing 112. In comparison, FIG. 7 illustrates voltage contours for a configuration for tunable component 100 in which fixed isolation landing 112 is grounded and movable actuator electrode 130 is continuous. Accordingly, those having ordinary skill in the art should recognize that electric fields in the vicinity of isolation bump 150, particularly at its contact surface, can be reduced, which can result in far less charging.

It should be noted that the voltage contour graphs for FIG. 6 and FIG. 7 are based on a device configuration where the isolation bump and isolation landing have approximately the same width (i.e. horizontal width in the context of these figures). These voltage contour graphs help to highlight the effect of setting the voltage potential of the isolation landing the same as the voltage potential of the isolation bump. By setting the voltage potential of these components the same, the voltage contour graphs show that electric fields are reduced at the point of contact leading to reduced charging. Similar or greater reductions in electric field can also be provided by altering the lengths/widths/diameter of the isolation landing and isolation bump as described above with respect to FIG. 2A through FIG. 2E.

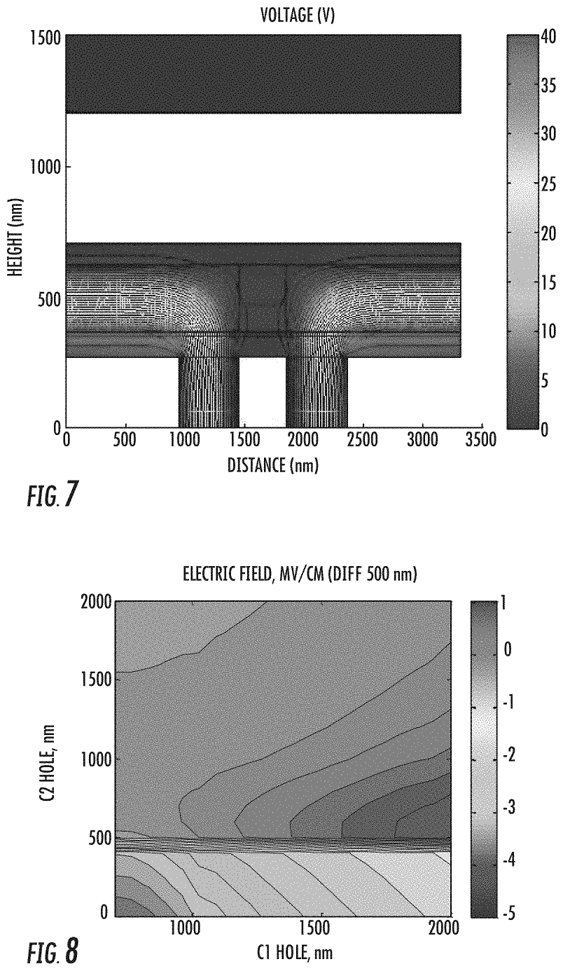

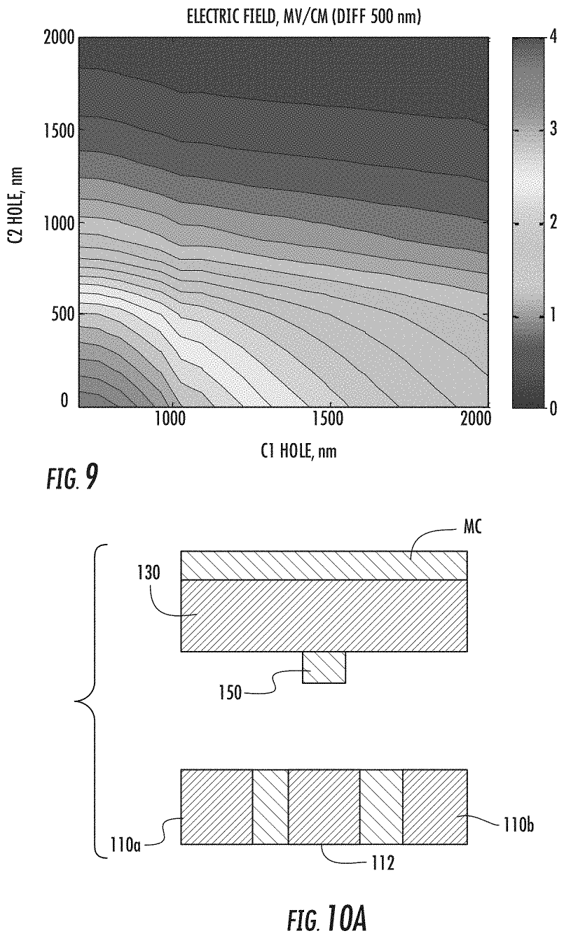

Similarly, the electric field that is developed at the center of isolation bump 150 can vary depending on the configuration of movable actuator electrode 130 (e.g., having a hole at or near isolation bump 150, as a conformal layer, or having a movable isolation fill 132) and the configuration of fixed actuator electrode 110 (e.g., having fixed isolation landing 112 defined therein). In the particular configurations shown, for example, the electric fields developed with a grounded fixed isolation landing 112 (See, e.g., FIG. 8) can be compared against those with a floating fixed landing (See, e.g., FIG. 9). As can be seen from these results, grounding of isolation bump 150 and fixed isolation landing 112 can induce a lower field in the dielectric contact region of isolation bump 150.

The present subject matter can be embodied in other forms without departure from the spirit and essential characteristics thereof. The embodiments described therefore are to be considered in all respects as illustrative and not restrictive. Although the present subject matter has been described in terms of certain preferred embodiments, other embodiments that are apparent to those of ordinary skill in the art are also within the scope of the present subject matter.

What is claimed is:

1. A tunable component comprising:
a fixed actuator electrode positioned on a substrate;
a movable actuator electrode carried on a movable component that is suspended over the substrate, wherein the movable actuator electrode is selectively movable toward the fixed actuator electrode;
one or more isolation bumps positioned between the fixed actuator electrode and the movable actuator electrode, the one or more isolation bumps being configured to prevent contact between the fixed actuator electrode and the movable actuator electrode; and
one or more fixed isolation landing that is isolated within a portion of the fixed actuator electrode, the one or more fixed isolation landing being positioned at, near, and/or substantially aligned with a respective one of the one or more isolation bumps, the one or more fixed isolation landing being configured to inhibit the development of an electric field in the respective isolation bump;
wherein each fixed isolation landing is spaced apart from the fixed actuator electrode on either side of the fixed isolation landing;
wherein a ratio of a first distance, the first distance being a distance between an edge of an isolation bump of the one or more isolation bumps and an edge of a fixed isolation landing of the one or more fixed isolation landing, to a second distance, the second distance being a distance between an edge of the isolation landing and an edge of the fixed actuator electrode, is greater than 0.5 to 1 and less than 4 to 1.

2. The tunable component of claim 1, wherein at least some of the one or more isolation bumps are attached to the movable component.

3. The tunable component of claim 1, wherein each of the one or more isolation bumps are attached to a respective fixed isolation landing.

4. The tunable component of claim 1, wherein the fixed isolation landing is electrically isolated.

5. The tunable component of claim 1, wherein the fixed isolation landing is connected to a ground potential.

6. The tunable component of claim 1, wherein the fixed isolation landing is connected to a potential that is substantially similar to a potential connected to the fixed actuator electrode.

7. The tunable component of claim 1, wherein the fixed isolation landing is connected to a potential that is different than a potential connected to the fixed actuator electrode.

8. The tunable component of claim 1, comprising at least one of a fixed dielectric material layer provided on a surface of the fixed actuator electrode that faces the movable actuator electrode and a movable dielectric material layer provided on a surface of them movable actuator electrode that faces the fixed actuator electrode.

9. The tunable component of claim 1, wherein the movable actuator electrode is patterned to include a hole that is at, near, and/or substantially aligned with each of the one or more isolation bumps.

10. The tunable component of claim 1, comprising a movable isolation fill that is isolated within a portion of the movable actuator electrode that is at, near, and/or substantially aligned with each of the one or more isolation bumps.

11. A tunable component comprising:
a fixed actuator electrode positioned on a substrate;
a movable actuator electrode carried on a movable component that is suspended over the substrate, wherein the movable actuator electrode is selectively movable toward the fixed actuator electrode;
one or more isolation bumps positioned between the fixed actuator electrode and the movable actuator electrode, the one or more isolation bumps being configured to prevent contact between the fixed actuator electrode and the movable actuator electrode; and
one or more fixed isolation landing that is isolated within a portion of the fixed actuator electrode, the one or more fixed isolation landing being positioned at, near, and/or substantially aligned with a respective one of the one or more isolation bumps, the one or more fixed isolation landing being configured to inhibit the development of an electric field in the respective isolation bump;
wherein an amount that each edge of each isolation landing extends beyond a respective edge of the respective one of the one or more isolation bumps is between and including about 1 and 6.5 times greater than a height of the respective one isolation bump, where the height of the respective one isolation bump is measured by an amount the respective one isolation bump extends between the fixed actuator electrode and the movable actuator electrode.

12. The tunable component of claim 11, wherein at least some of the one or more isolation bumps are attached to the movable component.

13. The tunable component of claim 11, wherein each of the one or more isolation bumps are attached to a respective fixed isolation landing.

14. The tunable component of claim 11, wherein the fixed isolation landing is electrically isolated.

15. The tunable component of claim 11, wherein the fixed isolation landing is connected to a ground potential.

16. The tunable component of claim 11, wherein the fixed isolation landing is connected to a potential that is substantially similar to a potential connected to the fixed actuator electrode.

17. The tunable component of claim 11, wherein the fixed isolation landing is connected to a potential that is different than a potential connected to the fixed actuator electrode.

18. The tunable component of claim 11, comprising at least one of a fixed dielectric material layer provided on a surface of the fixed actuator electrode that faces the movable actuator electrode and a movable dielectric material layer provided on a surface of them movable actuator electrode that faces the fixed actuator electrode.

19. The tunable component of claim 11, wherein the movable actuator electrode is patterned to include a hole that is at, near, and/or substantially aligned with each of the one or more isolation bumps.

20. The tunable component of claim 11, comprising a movable isolation fill that is isolated within a portion of the movable actuator electrode that is at, near, and/or substantially aligned with each of the one or more isolation bumps.
